(19) United States
(12) Patent Application Publication
(10) Pub. No.: US 2017/0023656 A1
(43) Pub. Date: Jan. 26, 2017

(54) MULTI-PARAMETER FUNCTIONAL MAGNETIC RESONANCE IMAGING

(71) Applicant: Variety Children's Hospital d/b/a Nicklaus Children's Hospital, Miami, FL (US)

(72) Inventor: Byron Bernal, Miami, FL (US)

(21) Appl. No.: 14/806,104

(22) Filed: Jul. 22, 2015

(51) Int. Cl. G01R 33/48

(52) U.S. Cl. CPC G01R 33/4806

(57) ABSTRACT

Magnetic resonance imaging methods and apparatuses that can enhance and speed up acquisition of functional magnetic resonance images are provided. An imaging system can generate a functional image from a magnetic resonance image collecting a magnetic resonance signal from a patient who does one or more tasks as directed. A plurality of functional images along a time series can be generated by separating a plurality of magnetic resonance images generated along the time series during a collecting period into image groups, each corresponding to a predetermined temporal phase. The resting period and a task-execution period can be repeated a plurality of times along the time series during the collection period. A statistical process can then be performed on each of the image groups, and the functional images can be displayed by a display unit.

### FIELD OF THE INVENTION

The present invention relates to a magnetic resonance imaging system and a method of performing multi-parameter functional magnetic resonance imaging.

### BACKGROUND OF THE INVENTION

Magnetic Resonance Imaging (MRI) systems have been used not only for morphological image diagnosis, but also for functional image diagnosis. More specifically, an MRI apparatus is capable of providing a functional image in which brain activities are expressed by using a method called functional Magnetic Resonance Imaging (fMRI). Such functional images may obtained sequentially, each one of which occurs during some type of action or stimulus, or a resting period. Each image may be correlated to one specific type of activity to evaluate the brain during various functions.

Generally, fMRI methods generate multiple MRI images in which various activated areas of the brain are expressed by utilizing a blood-oxygenation-level-dependent effect. In an area of the brain that has been activated by a movement or a stimulus, the blood flow rate tends to increase. Also, because oxygen is supplied from the capillaries to nerve cells in the activated area, hemoglobin combined with oxygen (i.e., oxidized hemoglobin) is reduced so as to become reduced hemoglobin. In this situation, the amount of increase in oxygen consumption of the nerve cells is lower than the degree with which the blood flow rate increases. As a result, the amount of oxidized hemoglobin in the venous blood within the activated area increases in a relative manner. In addition, oxidized hemoglobin is more difficult to be magnetized than reduced hemoglobin is. In other words, a phenomenon may occur in which an activated area of the brain has a magnetic susceptibility decrease, so that the intensity of the magnetic resonance signal changes. The result produces images and signals that may be mapped.

### SUMMARY OF THE INVENTION

The present invention provides advantageous magnetic resonance imaging methods and apparatuses that can enhance and speed up acquisition of functional magnetic resonance images.

In an embodiment, an apparatus can include: an image-generating unit configured to generate magnetic resonance images by acquiring magnetic resonance signals from an examined patient who repeatedly executes a task with an intermission resting period; a functional-image-generating unit configured to generate a functional-diagnosis-purpose magnetic resonance image from said magnetic resonance images; an image-generation-controlling unit configured to control the functional-image-generating unit to generate a plurality of functional images along a time series by separating a plurality of magnetic resonance images that have been generated along the time series during a collecting period into image groups and by performing a statistical process on each of the separated image groups; and a display-controlling unit configured to cause the plurality of functional images along the time series that have been generated under control of the image-generation-controlling unit to be displayed by a display unit. Each of the image groups can correspond to a predetermined temporal phase, and the collecting period can be configured such that the resting period and a task-execution period during which the task is executed are repeated therein a plurality of times along the time series.

In another embodiment, a method of obtaining functional magnetic resonance images can include generating a functional magnetic resonance image from a magnetic resonance image that has been generated by collecting a magnetic resonance signal from a patient, wherein the patient repeatedly executes at least one task simultaneously with a sensory stimulus.

In another embodiment, an image processing method can include: generating a functional image from a plurality of medical images that have been generated along a time series; controlling a functional-image-generating unit to generate a plurality of functional images along the time series; and exercising control so that the plurality of functional images along the time series are displayed by a display unit.

### BRIEF DESCRIPTION OF THE DRAWINGS

FIG. 1 is an illustration of an example of multiple-parameter functional magnetic resonance imaging according to the present invention.

FIG. 2 is an illustration of an example of multiple-parameter functional magnetic resonance imaging according to the present invention.

### DETAILED DISCLOSURE

The present invention provides advantageous magnetic resonance imaging methods and apparatuses that can enhance and speed up acquisition of functional magnetic resonance images. Embodiments of the subject invention advantageously allow for reduction of time of a functional magnetic resonance imaging (fMRI), reduction of time for post-processing of an fMRI study, full controlled performance, ease of performing fMRI studies, the possibility to translate to other languages while keeping the structure and level of difficulty, and the ability to increase yield of successful studies, in particular in pediatrics.

Using fMRI, it is possible to specify a brain function activated site by generating a magnetic resonance image while an examined patient continuously and repeatedly performs a task, activating for example the motor area, the visual area, the auditory area, the language area, the sensory cortex, and similar areas of the brain. Intermissions of resting periods, each called a “rest,” provide greater contrasting images between each type of active periods and resting periods. By comparing images corresponding to task periods with those corresponding to rest periods, a map and other diagnostic tools and evaluations may be made and conducted. In addition, by comparing images that have been taken, for example, while tasks that have mutually-different contents are being executed, it is possible to specify a site that is activated during all the mutually-different tasks in common with one another and to specify a site that is peculiarly activated during each of the mutually-different tasks.

An example of an image analyzing process to specify a brain function activated site can include the following steps: first, an average image of all the images during the rest periods, and an average image of all the images during the task periods are obtained. Subsequently, a “t-test” is performed for determining a statistically significant difference based on a difference value and a standard error between the two group's mean and standard error values, so that a “t-value image” is generated as an fMRI original image. Alternatively, a linear correlation coefficient may be calculated, and also a correlation coefficient between pixel values of the fMRI original image and a reference function describing the resting/task period time frame is calculated, so that a correlation coefficient image is generated as an fMRI image.

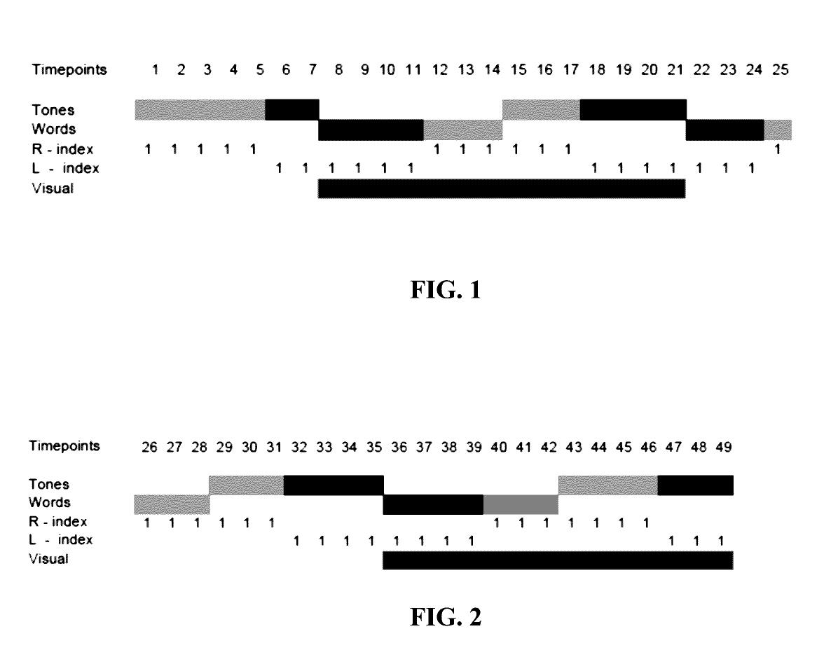

In this situation, a setting for the lengths of the time periods during which the rests and the tasks are executed is designed with blocks that are arranged with predetermined intervals. More specifically, the setting for the lengths of the time periods during which the rests and the tasks are executed is expressed with a designed formation in which model blocks including rest-period blocks for having a rest and the task-period blocks for activating the brain are arranged along the time series. Thus, the setting is called a “block setting,” which is shown in FIGS. 1 and 2.

A block setting process can be performed by an operator (e.g., a medical doctor) by inputting, as parameters, numerical values such as the quantity of rest-period blocks and task-period blocks and the number of times the rests and the tasks are repeatedly executed, together with the type of the task. For example, the parameters are input by using temporal phases that are expressed by using a repetition time (a “TR”) as a unit. Further, the block setting is used during an image analyzing process, which is performed after the images during the rest periods and the task periods have been collected.

Currently, there are often situations in which it takes a certain period of time for the brain to be activated after being stimulated, depending on the stimulus applied to the examined patient. The fMRI image is generated by using the data that has been collected during all the task periods and all the rest periods pertaining to the same series, each series characterized by a specific stimulus type that targets specific brain function as well. In an example clinical setting, approximately three to six series may be conducted.

It is desirable to obtain fMRI images in a shorter period of time, which benefits and is more convenient for the patient and the patient's family, aids in answering many patient questions, augments compliance, and reduces patient discomfort through lower procedure time, while also allowing an MRI system to treat more patients. It is therefore desirable to provide an MRI system to both enhance and greatly speed up acquisition of functional magnetic resonance images. The present invention provides advantageous magnetic resonance imaging methods and apparatuses that can enhance and speed up acquisition of functional magnetic resonance images.

In an embodiment, an apparatus can include: an image-generating unit configured to generate magnetic resonance images by acquiring magnetic resonance signals from an examined patient who repeatedly executes a task with an intermission resting period; a functional-image-generating unit configured to generate a functional-diagnosis-purpose magnetic resonance image from said magnetic resonance images; an image-generation-controlling unit configured to control the functional-image-generating unit to generate a plurality of functional images along a time series by separating a plurality of magnetic resonance images that have been generated along the time series during a collecting period into image groups and by performing a statistical process on each of the separated image groups; and a display-controlling unit configured to cause the plurality of functional images along the time series that have been generated under control of the image-generation-controlling unit to be displayed by a display unit. Each of the image groups can correspond to a predetermined temporal phase, and the collecting period can be configured such that the resting period and a task-execution period during which the task is executed are repeated therein a plurality of times along the time series.

In an embodiment, a magnetic resonance imaging method can include: generating (e.g., using an image-generating unit) magnetic resonance images by acquiring magnetic resonance signals from an examined patient who repeatedly executes a task with an intermission resting period; generating (e.g., using a functional-image-generating unit) a functional-diagnosis-purpose magnetic resonance image from said magnetic resonance images; generating (e.g., using an image-generation-controlling unit to control a functional-image-generating unit) a plurality of functional images along a time series by separating a plurality of magnetic resonance images that have been generated along the time series during a collecting period into image groups and by performing a statistical process on each of the separated image groups; and displaying the plurality of functional images along the time series that have been generated (e.g., generated under control of the image-generation-controlling unit). The displaying can be done using, e.g., a display-controlling unit configured to cause the plurality of functional images to be displayed by a display unit. Each of the image groups can correspond to a predetermined temporal phase, and the collecting period can be configured such that the resting period and a task-execution period during which the task is executed are repeated therein a plurality of times along the time series.

In another embodiment, an image-processing apparatus can include: a functional-image-generating unit that generates a functional image from an examined patient who repeatedly executes a task with or without an intermission of a resting period; an image-generation-controlling unit that controls the functional-image-generating unit to generate a plurality of functional images along a time series by separating a plurality of magnetic resonance images that have been generated along the time series during a collecting period into image groups and by performing a statistical process on each of the separated image groups; and a display-controlling unit that exercises control so that the plurality of functional images along the time series that have been generated under control of the image generation controlling unit are displayed by a display unit. Each of the image groups can correspond to a predetermined temporal phase, and the collecting period can be configured so that the resting period and a task-execution period during which the task is executed are repeated therein a plurality of times along the time series.

In an embodiment, a method of obtaining functional magnetic resonance images can include generating a functional magnetic resonance image from a magnetic resonance image that has been generated by collecting a magnetic resonance signal from an examined patient who repeatedly executes at least one task simultaneously with a sensory stimulus. In a further embodiment, the method can also include obtaining a magnetic resonance signal during continued performance of the at least one task, while simultaneously presenting a different stimulus. The magnetic resonance signal may also be obtained during a rest period. A functional magnetic resonance signal may also be obtained using a coupling between an antagonic cognitive task and an antagonic modal response (simultaneous distinct functional brain domains).

In an embodiment of the subject invention, an image processing method can generate a functional image (e.g., a functional-diagnosis-purpose medical image) from a plurality of medical images that have been generated along a time series. The method can include: controlling a functional-image-generating unit to generate a plurality of functional images along the time series by separating the plurality of medical images that have been generated along the time series into image groups and by performing a statistical process on each of the image groups resulting from the separation; and exercising control so that the plurality of functional images along the time series that have been generated under control of an image-generation-controlling unit are displayed by a display unit. Each image group can correspond to a predetermined temporal phase.

According to embodiments of the subject invention, computational analysis of different regressors allows for extraction of certain brain functions, including but not necessarily limited to visual function, expressive and receptive language, right-motor representation for left hand, and left-motor representation for right hand.

Embodiments of the subject invention advantageously allow for reduction of time of an fMRI study from 20-40 minutes to a much lower time (e.g., ten minutes or less). In many embodiments, time for an fMRI study can be reduced to six minutes, or even less.

Embodiments of the subject invention advantageously allow for reduction of time for post-processing of an fMRI study from 80 minutes to a much lower time (e.g., 30 minutes or less). In many embodiments, time for post-processing of an fMRI study can be reduced to 24 minutes, or even less, using a 2 GHz dual-core processor computer.

In addition, embodiments of the subject invention advantageously provide full controlled performance, ease of performing fMRI studies, the possibility to translate to other languages while keeping the structure and level of difficulty, and the ability to increase yield of successful studies, in particular in pediatrics (due at least in part to the time reduction).

The methods and processes described herein can be embodied as code and/or data. The software code and data described herein can be stored on one or more computer-readable media, which may include any device or medium that can store code and/or data for use by a computer system. When a computer system reads and executes the code and/or data stored on a computer-readable medium, the computer system performs the methods and processes embodied as data structures and code stored within the computer-readable storage medium.

It should be appreciated by those skilled in the art that computer-readable media include removable and non-removable structures/devices that can be used for storage of information, such as computer-readable instructions, data structures, program modules, and other data used by a computing system/environment. A computer-readable medium includes, but is not limited to, volatile memory such as random access memories (RAM, DRAM, SRAM); and non-volatile memory such as flash memory, various read-only-memories (ROM, PROM, EPROM, EEPROM), magnetic and ferromagnetic/ferroelectric memories (MRAM, FeRAM), and magnetic and optical storage devices (hard drives, magnetic tape, CDs, DVDs); network devices; or other media now known or later developed that is capable of storing computer-readable information/data. Computer-readable media should not be construed or interpreted to include any propagating signals.

A greater understanding of the present invention and of its many advantages may be had from the following examples, given by way of illustration. The following examples are illustrative of some of the methods, applications, embodiments and variants of the present invention. They are, of course, not to be considered as limiting the invention. Numerous changes and modifications can be made with respect to the invention.

### Example 1

An fMRI study was performed according to methods of the subject invention. Auditory and visual stimuli were presented simultaneously. The auditory stimulus was a pair of tones vs. a pair of words. The tone pair could be the same or different, and the word pair could be synonyms or antonyms. For the response, the subject moved the right index finger for any pair (tones or words) that were the same, and the subject moved the left index finger for any pair that were different. The series included 150 time points, with each time point lasting 2 seconds. The total duration was six minutes, and the difficulty level was easy. FIG. 1 is a graphical representation of the first 25 time points, and FIG. 2 is a graphical representation of time points 26-49. Referring to FIGS. 1 and 2, green blocks represent synonyms or a pair with the same tones, and red blocks represent antonyms or a pair with different tones. A “1” is a motor response accordingly with the pair type presented, and empty blocks or gray blocks represent no stimulus presented. Auditory stimuli were presented throughout these 49 time points.

Computational analysis of different regressors allowed for extraction of the following brain functions: visual function; expressive and receptive language; right-motor representation for left hand; and left-motor representation for right hand. This fMRI study took only six minutes, compared to the 20-40 minutes of conventional fMRI studies. The post-processing time of this fMRI study was only 24 minutes in a 2 GHz, dual core computer, compared to 80 minutes with conventional fMRI studies. Studies of this type have a low difficulty level, provide full controlled performance, are possible to translate to other languages while keeping the structure and the difficulty level, and lead to an increased yield of successful studies (in particular in pediatrics, due at least in part to the time reduction).

### Example 2

An fMRI study was performed according to methods of the subject invention. Auditory and visual stimuli were presented simultaneously. The auditory stimulus was a pair of tones vs. a pair of words. The tone pair could be the same or different, and the word pair could be synonyms or antonyms. For the response, the subject moved the right index finger for any pair (tones or words) that were the same, and the subject moved the left index finger for any pair that were different. The series included 150 time points, with each time point lasting 2 seconds. The total duration was six minutes. Table 1 shows results of the first 17 time points. Referring to Table 1, a “0” indicates no stimulus (Visual) or no response (MR-RH, MR-LH), a “1” indicates a motor response (MR-RH, MR-LH) or a visual stimulus being on (Visual), an “=” indicates synonyms (Words) or equal pitch (Tones), and an ≠ indicates antonyms (Words) or different pitch (Tones). The “MR-RH” row is for motor response of the right hand, and the “MR-LH” row is for motor response of the left hand.

Computational analysis of different regressors allowed for extraction of the following brain functions: visual function; expressive and receptive language; right-motor representation for left hand; and left-motor representation for right hand. This fMRI study took only six minutes, compared to the 20-40 minutes of conventional fMRI studies. The post-processing time of this fMRI study was only 24 minutes in a 2 GHz, dual core computer, compared to 80 minutes with conventional fMRI studies. Studies of this type have a low difficulty level, provide full controlled performance, are possible to translate to other languages while keeping the structure and the difficulty level, and lead to an increased yield of successful studies (in particular in pediatrics, due at least in part to the time reduction).

TABLE 1
Stimulus/response time line.

| | Time-point: | | | | | | | | | | | | | | | | |
|---|---|---|---|---|---|---|---|---|---|---|---|---|---|---|---|---|---|
| | 1 | 2 | 3 | 4 | 5 | 6 | 7 | 8 | 9 | 10 | 11 | 12 | 13 | 14 | 15 | 16 | 17 |
| Tones: | = | = | = | = | = | ≠ | ≠ | 0 | 0 | 0 | 0 | 0 | 0 | = | = | = | = |
| Words: | 0 | 0 | 0 | 0 | 0 | 0 | 0 | ≠ | ≠ | ≠ | ≠ | = | = | = | 0 | 0 | 0 |
| MR - RH | 1 | 1 | 1 | 1 | 1 | 0 | 0 | 0 | 0 | 0 | 0 | 1 | 1 | 1 | 1 | 1 | 1 |
| MR - LH | 0 | 0 | 0 | 0 | 0 | 1 | 1 | 1 | 1 | 1 | 1 | 0 | 0 | 0 | 0 | 0 | 0 |
| Visual: | 0 | 0 | 0 | 0 | 0 | 0 | 0 | 0 | 1 | 1 | 1 | 1 | 1 | 1 | 1 | 1 | 1 |

Conventions:
0, no stimulus/no response;
1, molor response, or visual stimulus ON;
“=”, synonyms (words) or equal pitch (tones);
“≠”, antonyms (words) or different pitch tones.

It should be understood that the examples and embodiments described herein are for illustrative purposes only and that various modifications or changes in light thereof will be suggested to persons skilled in the art and are to be included within the spirit and purview of this application.

All patents, patent applications, provisional applications, and publications referred to or cited herein are incorporated by reference in their entirety, including all figures and tables, to the extent they are not inconsistent with the explicit teachings of this specification.

What is claimed is:

1. A medical method of obtaining functional magnetic resonance images, the method comprising:
generating a functional magnetic resonance image from a magnetic resonance image that has been generated by collecting a magnetic resonance signal from a patient,
wherein the patient repeatedly executes at least one task simultaneously with a sensory stimulus.

2. The medical method according to claim 1, further comprising obtaining a magnetic resonance signal during continued performance of the at least one task, while simultaneously presenting a different stimulus.

3. The medical method according to claim 1, further comprising obtaining a magnetic resonance signal during a rest period.

4. The medical method according to claim 1, further comprising obtaining a functional magnetic resonance signal using a coupling between an antagonic cognitive task and an antagonic modal response.

5. A medical image processing method, comprising:
generating a functional image from a plurality of medical images that have been generated along a time series;
controlling a functional-image-generating unit to generate a plurality of functional images along the time series; and
exercising control so that the plurality of functional images along the time series are displayed by a display unit.

6. The medical image processing method according to claim 5, wherein the functional image is a functional-diagnosis-purpose medical image.

7. The medical image processing method according to claim 5, wherein controlling a functional-image-generating unit to generate a plurality of functional images along the time series comprises:
separating the plurality of medical images that have been generated along the time series into image groups corresponding to different stimuli; and
performing a statistical process on each of the image groups resulting from the separation.

8. The medical image processing method according to claim 7, wherein each of the image groups corresponds to a predetermined temporal phase.

9. The medical image processing method according to claim 5, wherein the plurality of functional images along the time series are generated under control of an image-generation-controlling unit.
